(19) United States
(12) Patent Application Publication
(10) Pub. No.: US 2025/0130382 A1
(43) Pub. Date: Apr. 24, 2025

(54) OPTICAL TRANSCEIVER HEAT SINK

(71) Applicant: Vecima Networks Inc., Victoria (CA)

(72) Inventors: Clinton Wade BINKLEY, Saskatoon (CA); Colin Andrew HOWLETT, Victoria (CA); Brent William GRIFFITHS, Saskatoon (CA); Amirhossein RAVANBOD, Saskatoon (CA)

(21) Appl. No.: 18/920,209

(22) Filed: Oct. 18, 2024

Related U.S. Application Data
(60) Provisional application No. 63/592,077, filed on Oct. 20, 2023.

(51) Int. Cl. G02B 6/42; H05K 7/20

(52) U.S. Cl. CPC G02B 6/4269; G02B 6/4246; H05K 7/2039

(57) ABSTRACT

An optical transceiver heat sink module assembly for use with optical transceivers comprising an optical transceiver cover, a module cover, a module base and one or more thermal gaskets is described.

### CROSS-REFERENCE TO RELATED APPLICATIONS

The present application claims priority from U.S. Provisional Application No. 63/592,077 filed on Oct. 20, 2023, incorporated herein by reference in its entirety.

### TECHNICAL FIELD

The following relates generally to heat sinks. An embodiment of the invention relates to heat sink assemblies for use with optical transceivers

### BACKGROUND

Optical transceivers are often installed in severe environmental conditions where long-term operation is essential. Therefore, it is critical to have an efficient heat sink design to maintain optical transceiver operation within their maximum temperature ratings.

There are currently no heat sink design solutions available in the market with sufficient heat transfer capabilities to enable operation of high-power optical transceivers in severe environmental conditions with restricted air flow. Also, next generation optical transceivers will operate at higher data rates with increased heat dissipation requirements and therefore having an improved heat sink design solution will be of even greater importance to future products.

### SUMMARY OF THE INVENTION

In one broad aspect, there is provided an optical transceiver heat sink module assembly for use with optical transceivers comprising: an optical transceiver cover adapted for attachment to a module cover and a module base; a module cover; a module base; and one or more thermal gaskets disposed at contact points between the optical transceiver cover, the module cover, the module base and one or more optical transceivers, wherein, when assembled, the main heat dissipation path is from the one or more optical transceivers to the optical transceiver cover to the module base through a back wall of the optical heat sink module assembly.

In another broad aspect, there is provided an optical transceiver heat sink module assembly as described above further comprising one or more guides disposed on the module cover to guide the optical transceivers into position within the assembly.

In another broad aspect, there is described an optical transceiver heat sink assembly as generally described in one or more paragraphs above, comprising one or more guides disposed on the transceiver cover to guide the optical transceivers into position within the assembly.

In another broad aspect, there is described an optical transceiver heat sink assembly as generally described in one or more paragraphs above, wherein the guides on the module cover are walls.

In another broad aspect, there is described an optical transceiver heat sink assembly as generally described in one or more paragraphs above, wherein the guides on the transceiver cover are walls.

In another broad aspect, there is described an optical transceiver heat sink assembly as generally described in one or more paragraphs above, wherein the optical transceiver cover is attached to the module cover and the module base by one or more screws.

In another broad aspect, there is described an optical transceiver heat sink assembly as generally described in one or more paragraphs above, wherein the torque force applied to the one or more screws is 5 inch pounds.

In another broad aspect, there is described an optical transceiver heat sink assembly as generally described in one or more paragraphs above, wherein four screws are used to attach the transceiver cover to the module cover and the module base.

In another broad aspect, there is described an optical transceiver heat sink assembly as generally described in one or more paragraphs above, wherein the optical transceiver cover is attached to the module cover and the module base by one or more latches.

In another broad aspect, there is described an optical transceiver heat sink assembly as generally described in one or more paragraphs above, wherein the optical transceiver cover is attached to the module cover and the module base by one or more bolts.

In another broad aspect, there is described an optical transceiver heat sink assembly as generally described in one or more paragraphs above, wherein four bolts are used to attach the transceiver cover to the module cover and the module base.

### BRIEF DESCRIPTION OF THE DRAWINGS

Embodiments will now be described by way of example only with reference to the appended drawings wherein:

FIG. 1 shows a bottom perspective view optical transceiver cover of the invention;

FIG. 2 shows a top perspective view of the module cover of the invention;

FIG. 3 shows a top perspective view of elements of the invention;

FIG. 4 shows a top perspective view showing the transceivers inserted between the transceiver cover and the module cover;

FIG. 5A shows a top view of elements of the invention;

FIG. 5B shows a cross-section of elements of the invention taken from the line A-A in FIG. 5A; and

FIG. 5C shows additional enlarged detail from indicated area B of FIG. 5B.

### DETAILED DESCRIPTION OF THE INVENTION

The most common optical transceiver heat sink method uses an aluminum sheet metal cage that relies on a friction fit approach for heat transfer. The mating surfaces do not provide a sufficient heat transfer area between the optical transceiver and metal cage, resulting in a high thermal resistance interface.

There are cage manufacturers who have integrated heat sinks into their designs using small metal blocks or “slugs” that attach to the cage using springs and clips. These integrated slug designs have improved heat transfer area between the optical transceiver and heat sink. This implementation requires force to be applied to the slug causing increased friction between the optical transceiver and slug, however, making the optical transceiver insertion/removal process difficult.

In addition to metal slug implementations, other integrated heat sink technologies have been developed to balance trade-offs between heat transfer and insertion/removal force inherent in integrated cage heatsink approaches. One technology called a thermal bridge heat sink has an interleaved series of heat transfer plates attached to the cage using springs and allows the plates to conform to the optical transceiver mating surface. This thermal bridge technology eliminates the high insertion/removal force problem; however, the solution has a limited number of contact points between the heat sink and optical transceiver surface also resulting in a high thermal resistance interface.

The present invention is a design solution to keep optical transceivers operating within their maximum temperature ratings while in severe environmental conditions. The solution is achieved by eliminating the optical transceiver cage and instead using a top heat sink cover that is removable using screws or a mechanical latch mechanism and a fixed bottom heat sink. This design lowers the thermal resistance presented to the optical transceivers allowing them to maintain operation within their maximum temperature rating while in severe environmental conditions and/or with restricted airflow.

The clamping heat sink method is not as convenient as the friction fit cage implementations since the heat sink needs to be loosened during the optical transceiver install/removal process. The optical transceivers do not get replaced in the field very often, however, so this inconvenience is a very small drawback as compared with the thermal benefits of the design of the invention.

The optical transceiver heat sink solution presented herein removes the cage element from the incumbent designs and utilizes top and bottom heat sink components. The top heat sink uses a removable cover that is installed on top of the optical transceiver and fastened in place using bolts, screws or a mechanical latch mechanism. It will be appreciated that other fastening means may also be used to secure the removable cover such that a friction fit cage is not used. The top heat sink is the primary heat transfer path and contacts the top surface of the optical transceiver case directly. The top heat sink provides a large thermal mass and a low thermal resistance pathway for heat dissipation. The bottom heat sink is a base plate with a raised metal section that also provides optical transceiver mounting support. The bottom heat sink is a secondary heat transfer path and contacts the bottom surface of the optical transceiver case directly, also providing high thermal mass and a secondary low thermal resistance pathway.

Thermal pads are installed between the optical transceiver and top/bottom heat sinks to lower thermal resistance further and improve heat transfer.

The optical transceivers are installed/removed by either loosening or removing the top heat sink cover. Once the heat sink cover bolts, screws, or mechanical latch are loosened, the optical transceiver device is installed by pushing it into place using alignment features of the design and connected to its mating connector located on a printed circuit board. For removal, the optical transceiver is pulled from the port. The heat sink cover can also be completely removed for optical transceiver installation/removal.

The invention eliminates the friction fit thermal interface between the optical transceiver and heat sink and provides a higher-performing thermal interface. This allows optical transceiver operation within the maximum thermal rating when installed in extreme environments.

Optical fiber transport is a key technology to enable the delivery of fast and affordable bandwidth to business and residential users. Coherent optics is an evolving technology that is completely transforming optical transmission systems and is providing service providers with a significant upgrade path from standard speeds of 10 Gbps using WDM (wavelength-division multiplexed) technology to speeds of 100 Gbps, 200 Gbps, and 400 Gbps per wavelength using coherent technology.

Two of the major obstacles for the coherent optic upgrade path are the power consumption and thermal management. Over the last two decades, power ratings for pluggable optical transceivers have increased as technology evolved from direct detection to more power-intense coherent transmission: from 2 Watts for SFP devices to 3.5 Watts for QSFP devices and now to 14 Watts for QSSFP-DD and 21.1 Watts for OSFP devices. Half of the coherent transceiver's power is consumed in the digital signal processing (DSP) circuitry within the device, and as data bandwidth increases, so too does energy consumption and therefore heat generation.

The clamping heat sink method will be useful for these emerging coherent optical transceiver applications as it is more efficient and capable of greater heat dissipation. The friction fit heat sink methods may be sufficient for many indoor server environments that utilize high speed fans for cooling; however, all passive applications will benefit from using the clamping heat sink method.

Adding integrated heat pipes or thermoelectric coolers into the clamping heat sink could further improve heat transfer performance for other non DAA node applications.

The optical transceiver heat sink consists of three mechanical assemblies that include an optical transceiver cover 100, a module cover 101 and a module base 102.

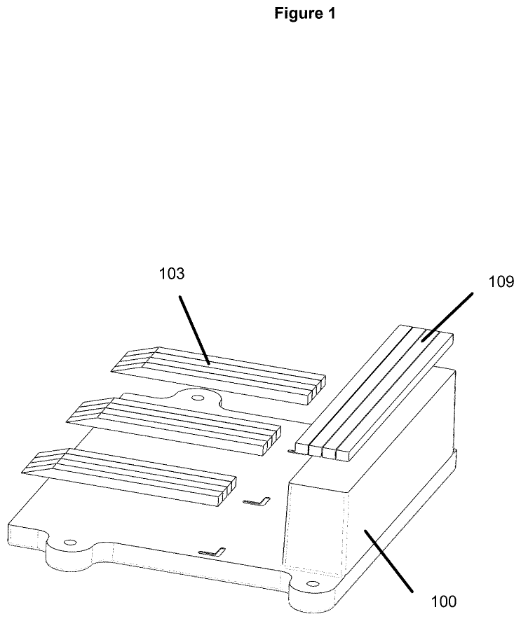

FIG. 1 shows the optical transceiver cover 100 in an inverted orientation. The optical transceiver cover 100 provides the heat sink contact surface to the optical transceivers. Since the two solid mating surfaces are not perfect due to unevenness and surface roughness, a thermally conductive gasket material 103 is used at the interface to improve heat transfer between the optical transceiver and heat sink by reducing the thermal resistance. The optical transceiver cover has a similar thermally conductive gasket material 109 used for the same purpose between the optical transceiver cover and module base.

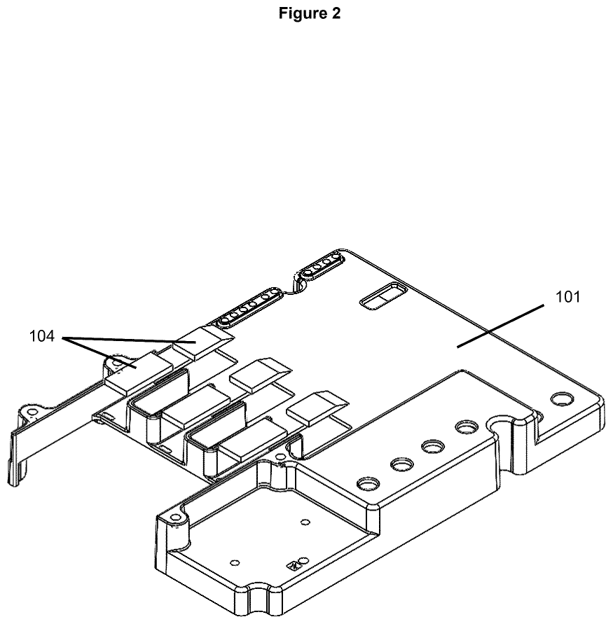

FIG. 2 shows the main module cover of an embodiment of the invention. As shown in FIG. 2, the main module cover provides support for the optical transceivers when installed into the module. The module cover has thermally conductive gasket material 104 that mates with the bottom surface of the optical transceiver to allow compensation for the non-perfect surface flatness between the two mating surfaces. In one embodiment, the optical transceiver cover 100 attaches to the main module cover 101 using four screws.

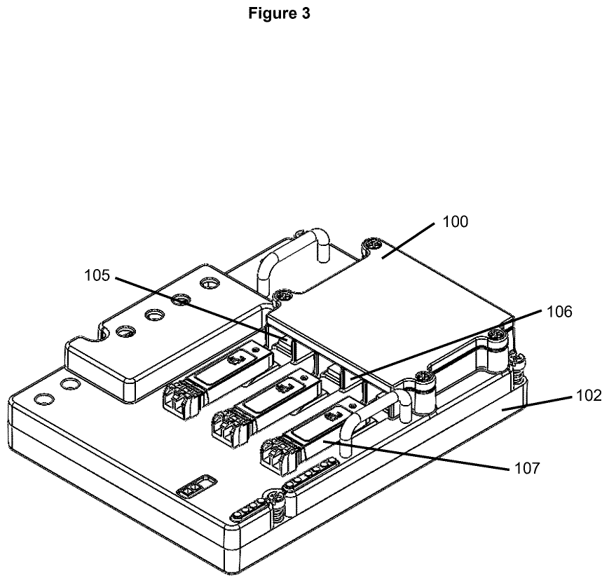

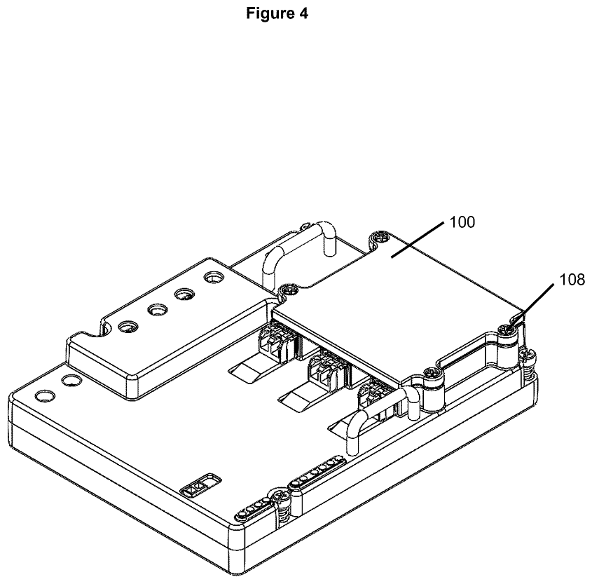

When the optical transceiver heat sink is fully assembled with all three mechanical assemblies including the optical transceiver cover 100, module cover 101 and module base 102, as shown in FIG. 3, the optical transceivers 107 are installed by loosening the four screws in the optical transceiver cover. The optical transceivers 107 slide into the front openings 105 using the module cover walls 106 to guide the optical transceivers to the mating connectors.

After the optical transceivers are installed, the four optical transceiver cover screws 108 are tightened with sufficient torque to compress the thermal gaskets to provide the optimized thermal path from the optical transceivers to the optical transceiver cover. In one embodiment of the invention, the torque may be 5 inch pounds.

While screws are described as an attachment mechanism directly above, it will be appreciated that other attachments could also be used such as, for example, bolts or latches.

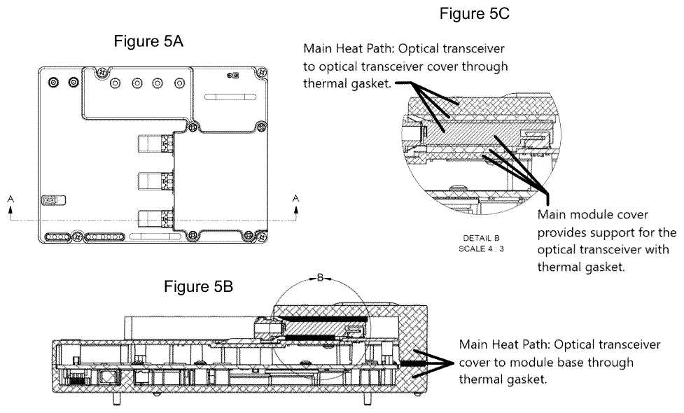

The main heat dissipation path is from the optical transceiver to the optical transceiver cover to the module base through the back wall of the module, as shown in FIGS. 5B and 5C.

A key element for heat transfer is to maximize the contact area between the optical transceiver and heat sink. The invention uses a method that has full contact between the heatsink and top surface of the optical transceiver.

A series of test iterations identified the optical transceiver top surface as the main heat path from the optical transceiver. The invention has a heat sink component that also makes contact with the bottom surface of the optical transceiver; however, it was shown by test that the bottom heat sink yielded no improvement to thermal performance. The bottom heat sink component is used to support the module.

It will be appreciated that more development time could be spent investigating if adding heat sink contact to the optical transceiver side walls would further improve performance. Adding side wall heat sink contact would have significant mechanical challenges and was not pursued. Additionally, adding integrated heat pipes or thermoelectric coolers into the clamping heat sink module could further improve heat transfer performance and additional investigations could precisely determine the benefits of incorporating these additional features.

For simplicity and clarity of illustration, where considered appropriate, reference numerals may be repeated among the figures to indicate corresponding or analogous elements. In addition, numerous specific details are set forth in order to provide a thorough understanding of the examples described herein. However, it will be understood by those of ordinary skill in the art that the examples described herein may be practiced without these specific details. In other instances, well-known methods, procedures and components have not been described in detail so as not to obscure the examples described herein. Also, the description is not to be considered as limiting the scope of the examples described herein.

Numerous specific details are set forth in order to provide a thorough understanding of the examples described herein. However, it will be understood by those of ordinary skill in the art that the examples described herein may be practiced without these specific details. In other instances, well-known methods, procedures and components have not been described in detail so as not to obscure the examples described herein. Also, the description is not to be considered as limiting the scope of the examples described herein.

It will be appreciated that the examples used herein are for illustrative purposes only. Different terminology can be used without departing from the principles expressed herein.

Although the above principles have been described with reference to certain specific examples, various modifications thereof will be apparent to those skilled in the art as outlined in the appended claims.

1. An optical transceiver heat sink module assembly for use with optical transceivers comprising:
an optical transceiver cover adapted for attachment to a module cover and a module base;
a module cover;
a module base; and
one or more thermal gaskets disposed at contact points between the optical transceiver cover, the module cover, the module base and one or more optical transceivers,
wherein, when assembled, the main heat dissipation path is from the one or more optical transceivers to the optical transceiver cover to the module base through a back wall of the optical heat sink module assembly.

2. The optical transceiver heat sink module assembly of claim 1 further comprising one or more guides disposed on the module cover to guide the optical transceivers into position within the assembly.

3. The optical transceiver heat sink module assembly of claim 1 further comprising one or more guides disposed on the transceiver cover to guide the optical transceivers into position within the assembly.

4. The optical transceiver heat sink module assembly of claim 2, wherein the guides are walls.

5. The optical transceiver heat sink module assembly of claim 3, wherein the guides are walls.

6. The optical transceiver heat sink module assembly of claim 1, wherein the optical transceiver cover is attached to the module cover and the module base by one or more screws.

7. The optical transceiver heat sink module assembly of claim 6, wherein the torque force applied to the one or more screws is 5 inch pounds.

8. The optical transceiver heat sink module assembly of claim 6, wherein four screws are used to attach the transceiver cover to the module cover and the module base.

9. The optical transceiver heat sink module assembly of claim 1, wherein the optical transceiver cover is attached to the module cover and the module base by one or more latches.

10. The optical transceiver heat sink module assembly of claim 1, wherein the optical transceiver cover is attached to the module cover and the module base by one or more bolts.

11. The optical transceiver heat sink module assembly of claim 10, wherein four bolts are used to attach the transceiver cover to the module cover and the module base.
